(19) United States
(12) Patent Application Publication
(10) Pub. No.: US 2026/0357426 A1
(43) Pub. Date: Nov. 12, 2026

(54) METHOD AND APPARATUS FOR FORMING BORON NITRIDE LAYER

(71) Applicant: ASM IP Holding B.V., Almere (NL)

(72) Inventors: João Ricardo Antunes Afonso, Tokyo (JP); Kai Okabe, Kawasaki-shi (JP); Ranjit Rohidas Borude, Leuven (BE); Hideaki Fukuda, Tokyo (JP); Jongbeom Choi, Sagamihara-shi (JP); Jaewoo Jeong, Tokyo (JP)

(21) Appl. No.: 19/638,348

(22) Filed: Apr. 3, 2026

Related U.S. Application Data
(60) Provisional application No. 63/785,190, filed on Apr. 8, 2025.

(51) Int. Cl. C23C 16/455; C07F 5/02; C07F 5/05; C23C 16/34; C23C 16/44; C23C 16/46; C23C 16/52; H10P 14/60; H10P 14/694

(52) U.S. Cl. CPC C23C 16/45536; C07F 5/027; C07F 5/05; C23C 16/342; C23C 16/4408; C23C 16/45544; C23C 16/45553; C23C 16/46; C23C 16/52; H10P 14/6339; H10P 14/694

(57) ABSTRACT

A method and apparatus for forming a boron nitride layer using inductively coupled plasma (ICP) is disclosed, addressing challenges in semiconductor processing, particularly for high aspect ratio structures. The method involves introducing a substrate with a three-dimensional structure into a reaction chamber and executing multiple deposition cycles. Each cycle includes providing a boron precursor in vapor phase and a reactive species generated from ICP. The reactant gas may include nitrogen and hydrogen, selected from ammonia, nitrogen/hydrogen mixtures, or hydrazine. The boron precursor can be boron triiodide, boron tribromide, or similar compounds. The process aims to achieve high conformality and film quality by reducing ion bombardment, utilizing high RF power for radical generation. This approach is applicable in semiconductor manufacturing, enhancing the uniformity and integrity of boron nitride layers in complex structures.

### CROSS-REFERENCE TO RELATED APPLICATIONS

This application claims priority to U.S. Provisional Patent Application Ser. No. 63/785,190 filed Apr. 8, 2025 and titled METHOD AND APPARATUS FOR FORMING BORON NITRIDE LAYER, the disclosure of which is hereby incorporated by reference in its entirety.

### FIELD OF INVENTION

The present disclosure relates to semiconductor processing technologies, specifically the formation of boron nitride layers using inductively coupled plasma for applications in high aspect ratio structures.

### BACKGROUND OF THE DISCLOSURE

In the field of semiconductor processing, the formation of certain layers is important for various applications, particularly in high aspect ratio structures. Traditional methods often rely on techniques that can lead to issues such as non-uniform film deposition and ion bombardment, adversely affecting the quality and conformality of these layers. These challenges are especially pronounced in complex three-dimensional structures, where achieving uniform coverage and maintaining the integrity of the film are important.

Existing techniques struggle to provide the necessary conformality and film quality due to limitations in plasma generation and precursor delivery. The ion bombardment associated with conventional methods can result in undesirable film characteristics, such as increased roughness and non-uniform crystal structures. Additionally, the use of certain precursors may not adequately address the need for high conformality in high aspect ratio structures. These shortcomings highlight the need for an improved method that can deliver high-quality layers with enhanced uniformity and reduced ion impact, thereby meeting the stringent requirements of modern semiconductor applications.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In one embodiment, the disclosure includes a method for forming a layer comprising boron and nitrogen on a substrate surface. The method involves introducing a substrate into a reaction chamber, wherein the substrate exhibits a three-dimensional structure that can include lateral and/or horizontal gaps, and executing a plurality of deposition cycles. Each deposition cycle comprises the steps of providing a boron precursor in vapor phase into the chamber and supplying a reactive species generated from an inductively-coupled plasma produced from a reactant gas.

In certain embodiments, the reactant gas comprises nitrogen and hydrogen and may be selected from ammonia, a nitrogen/hydrogen mixture, or hydrazine. In some embodiments, the plasma is formed in a remote plasma unit. In some embodiments, the boron precursor can be a molecule selected from boron triiodide, boron tribromide, boron trichloride, diboron tetrachloride, boron monofluoride, boron trifluoride, or diboron tetrafluoride, with some embodiments specifically employing boron tribromide. The method may further include a purge step after the provision of the boron precursor and additional purge after supplying the reactive species. Moreover, a carrier gas may be used to transport the boron reactant into the chamber. In some embodiments, the carrier gas comprises argon. In other embodiments, the reactant gas optionally serving as the carrier and being continuously fed. In certain embodiments, the deposited layer comprises amorphous boron nitride, and the plasma radiofrequency power is in the range of 4000 to 8000 W.

In another aspect of the disclosure, there is provided a semiconductor processing apparatus that includes a reaction chamber with a substrate support, a heater for heating the substrate, a remote plasma module with a radio frequency power source to generate plasma, a reactant gas source connected to the plasma module, a boron precursor source connected to the reaction chamber via precursor valves, and a controller. The controller is programmed to execute multiple deposition cycles, each involving the introduction of a boron precursor in vapor phase into the reaction chamber and the provision of a reactive species generated from plasma produced from a reactant gas.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a flow chart diagram illustrating the method for forming a boron nitride layer according to one embodiment of the disclosure.

FIG. 2 is a schematic diagram illustrating a device according to one embodiment of the disclosure.

FIG. 3 is a system diagram illustrating the components involved in the formation of a boron nitride layer according to one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term “precursor” can refer to a compound that participates in the chemical reaction that produces another compound. The term reactant can be used interchangeably with the term precursor. The term “inert gas” can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas.

As used herein, the term “purge” may refer to a procedure in which an inert or substantially inert gas is provided to a reactor chamber in between two pulses of gases which react with each other. For example, a purge or purging gas may be provided between pulses of two precursors, thus avoiding or at least reducing gas phase interactions between two precursors. It shall be understood that a purge can be effected either in time or in space, or both. For example in the case of temporal purges, a purge step can be used, e.g., in the temporal sequence of providing a first precursor to a reactor chamber, providing a purge gas to the reactor chamber, and providing a second precursor to the reactor chamber, wherein the substrate on which a layer is deposited does not move. In the case of spatial purges, a purge step can be effected by moving a substrate from a first location to which a first precursor is (e.g., continually) supplied, through a purge gas curtain, to a second location to which a second precursor is (e.g., continually) supplied.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments of the disclosure, the substrate may comprise a patterned substrate including high aspect ratio features, such as, for example, trench structures, vertical gap features, horizontal gap features, and/or fin structures. For example, the substrate may comprise one or more substantially vertical gap features and/or one or more substantially horizontal gap features. The term “gap feature” may refer to an opening or cavity disposed between opposing inclined sidewalls or two protrusions extending vertically from the surface of the substrate or opposing inclined sidewalls of an indentation extending vertically into the surface of the substrate. Such a gap feature may be referred to as a “vertical gap feature.” In some embodiments, the vertical gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method according to the disclosure.

The term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. The process may comprise a purge step between introducing precursors.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

As used herein, the term “plasma enhanced atomic layer deposition” (PEALD) may refer to an ALD process in which one or more precursors, reactants, and/or other gases are exposed to a plasma to form excited species.

As used herein, “boron nitride” can be a material that can be represented by a chemical formula that includes boron and nitrogen. In some embodiments, boron nitride may not include significant proportions of elements than boron and nitride. In some embodiments, the boron nitride comprises BN. In some embodiments, the boron nitride may consist essentially of BN. In some embodiments, the boron nitride may consist of boron nitride. A layer consisting of boron nitride may include an acceptable amount of impurities, such as hydrogen, carbon, iodine, bromine and/or the like that may originate from one or more precursors used to deposit boron nitride.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

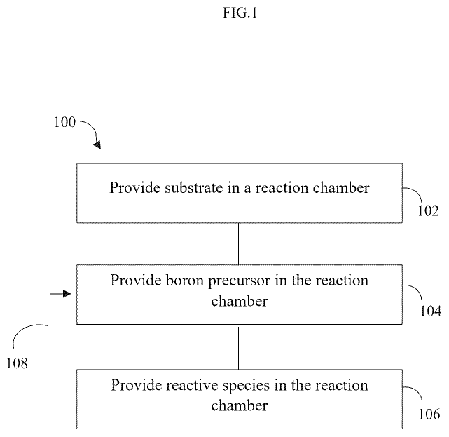

Turning now to the figures, FIG. 1 illustrates a method 100 in accordance with exemplary embodiments of the disclosure. Method 100 can be used to form boron nitride on a surface of a substrate. In the illustrated example, method 100 includes the steps of providing a substrate within a reaction chamber (102), providing a boron precursor to the reaction chamber (104), and providing a reactant to the reaction chamber (106).

During 102, a substrate is provided within a reaction chamber. The reaction chamber used during step 102 can be or include a reaction chamber of a chemical vapor deposition reactor system configured to perform a deposition process. The deposition process may be a chemical vapor deposition process and/or a cyclical deposition process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

In some embodiments, if desired, the exposed surfaces of the substrate may be pretreated to provide reactive sites. In some embodiments, a separate pretreatment step is not required. In some embodiments, the substrate is pretreated to provide a desired surface termination, for example, by exposing the substrate surface to a pretreatment plasma.

In some embodiments of the disclosure, the substrate disposed within the reaction chamber may be heated to a desired deposition temperature for a subsequent deposition. For example, the substrate may be heated to a substrate temperature of less than approximately 600 °C., less than approximately 500 °C., or less than approximately 450 °C., or less than approximately 400 °C., or less than approximately 350 °C., or less than approximately 300 °C., or less than approximately 250 °C., or even less than approximately 200 °C. In some embodiments of the disclosure, the substrate temperature during step 102 may be greater than room temperature, between approximately 300 °C. and approximately 600 °C. or approximately 350 °C. and approximately 550 °C. or approximately 200 °C. and approximately 400 °C. The lower temperatures may be preferred for plasma-assisted processes, while the higher temperatures may be desired for thermal deposition processes. The temperature during steps 104 and/or 106 can also be within these ranges.

In addition to controlling the temperature of the substrate, the pressure in the reaction chamber may also be regulated to enable deposition of desired boron nitride. In some embodiments, a pressure can be controlled between about 0.5 Torr and about 50 Torr (e.g., for thermal processes) or about 1 Torr and about 10 Torr (e.g., for plasma-enhanced processes). The pressure during steps 104 and/or 106 can also be within these ranges.

Once the temperature of substrate has been set to the desired deposition temperature and pressure in the reaction chamber has been regulated as desired, method 100 may continue to steps 104 and 106. When method 100 includes a CVD process, steps 104 and 106 can overlap. When method 100 includes a cyclical process, steps 104 and 106 can be performed sequentially with an intervening purge step between steps 104 and 106. During step 104, a boron precursor is provided to the reaction chamber. In the case of cyclical deposition, the boron precursor can be pulsed to the reaction chamber. The term “pulse” can be understood to comprise feeding a precursor into the reaction chamber for a predetermined amount of time. Unless otherwise noted, the term “pulse” does not restrict the length or duration of the pulse and a pulse may be any length of time. In some embodiments, in addition to a boron precursor, a gas may be provided to the reaction chamber continuously during a cyclical deposition process. In some embodiments, the gas may comprise both a gas for generation of reactive species utilized during a stage of the PEALD process and may also be utilized as a purge gas to remove excess reactants, reactive species, and reaction byproducts from the reaction chamber.

After an initial surface treatment, if necessary or desired, the boron precursor pulse may be supplied to the substrate. In accordance with some embodiments, the boron precursor may be supplied to the reaction chamber along with a carrier gas flow. In some embodiments, the boron precursor may comprise a volatile boron species that is reactive with the surface(s) of the substrate. The boron precursor pulse may self-saturate the substrate surfaces such that excess constituents of the boron precursor pulse do not further react with the molecular layer formed by this process.

The boron precursor pulse is preferably supplied as a vapor phase reactant. The boron precursor gas may be considered “volatile” for the purposes of the present disclosure if the species exhibits sufficient vapor pressure under the process conditions to transport species to the substrate surface in sufficient concentration to saturate the exposed surfaces.

In some embodiments, the vapor phase boron precursor comprises boron halide, borane, borazine or organoborane.

In some embodiments of the disclosure, the vapor phase boron precursor comprises boron and at least one halogen selected from iodine and bromine. In some cases, the boron precursor does not include fluorine and/or chlorine. In accordance with some embodiments of the disclosure, the boron precursor consists of boron and one or more of iodine and bromine. In some embodiments, the boron precursor comprises a molecule selected from the list consisting of boron triiodide, boron tribromide, boron trichloride, diboron tetrachloride, boron monofluoride, boron trifluoride and diboron tetrafluoride. For example, the boron precursor can be or include boron triiodide (BI₃) and/or boron tribromide (BBr₃).

In some embodiments, the vapor phase boron precursor comprises boron and hydrogen. In some embodiments, the boron precursor comprises borane, diborane, tetraborane, pentaborane, decaborane and borane-ammonia complex.

In some particular embodiments, the method as disclosed herein may provide that the boron precursor is represented by the following general formula (I)

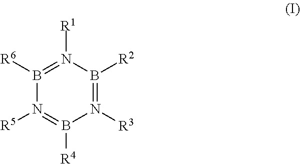

wherein R¹, R², R³, R⁴, R⁵, R⁶ are each independently selected from the group consisting of hydrogen, halogen, alkyl, alkenyl, and alkoxy.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C1-20alkyl”, as a group or part of a group, refers to a hydrocarbyl group of formula CₙH₂ₙ₊₁ wherein n is a number ranging from 1 to 20. Thus, for example, “C1-8alkyl” includes all linear or branched alkyl groups with between 1 and 8 carbon atoms, and thus includes methyl, ethyl, n-propyl, i-propyl, butyl, and its isomers (e.g., n-butyl, i-butyl, and t-butyl); pentyl and its isomers, hexyl, and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e., “alkylene,” this is intended to mean the alkyl group as defined herein having two single bonds as points of attachment to other groups. As used herein, the term “alkylene” also referred as “alkanediyl,” by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C3 20alkenyl groups are ethenyl, 2-propenyl, 2-butenyl, 3-butenyl, 2-pentenyl and its isomers, 2-hexenyl and its isomers, 2,4-pentadienyl, and the like.

The term “alkoxy” or “alkyloxy,” as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

Where an alkylene group is present, connectivity to the molecular structure of which it forms part may be through a common carbon atom or different carbon atom. To illustrate this applying the asterisk nomenclature of this disclosure, a C3alkylene group may be for example *—CH₂CH₂CH₂—*, *—CH(—CH₂CH₃)—* or *—CH₂CH(—CH₃)—*.

In some embodiments, the method as disclosed herein provides that for the one or boron precursor represented by the general formula (I), the alkyl is a C1-8alkyl, and more in particular a C1-4alkyl. More in particular the alkyl is a C1, C2, C3, C4, C5, C6, C7, and/or C8 alkyl.

In some embodiments, the method as disclosed herein provides that for the one or boron precursor represented by the general formula (I), the alkenyl is a C2-8alkenyl, and more in particular a C2-4alkenyl. More in particular the alkenyl is a C2, C3, C4, C5, C6, C7, and/or C8 alkenyl.

In some embodiments, the method as disclosed herein provides that for the one or boron precursor represented by the general formula (I), the alkoxy is a C1-8alkoxy, and more in particular a C1-4alkoxy. More in particular the alkoxy is a C1, C2, C3, C4, C5, C6, C7, and/or C8 alkoxy.

In some embodiments, the present disclosure provides that R¹, R², R³, R⁴, R⁵, R⁶ are each independently selected from the group consisting of hydrogen, halogen, C1-8alkyl, C2-8alkenyl, and C1-8alkoxy.

In some embodiments, the present disclosure provides that R¹, R², R³, R⁴, R⁵, R⁶ are each independently selected from the group consisting of hydrogen, halogen, C1-4alkyl, C2-4alkenyl, and C1-4alkoxy.

In particular embodiments, the method as disclosed herein provides that the one or more boron precursor may comprise borazine or a substituted borazine.

In some embodiments the boron precursor comprises a organoborane comprising alkyl borane or alkylamino borane. The boron precursor may comprises a molecule selected from the list consisting of trimethylborane, triethylborane, 3-tris-(dimethylamino)borane, dimethylamine borane, triethylamine borane.

In some embodiments of the disclosure, the boron precursor may be pulsed into the reaction chamber for a time period from about 0.05 seconds to about 5.0 seconds, or from about 0.1 seconds to about 3 seconds, or even about 0.2 seconds to about 1.0 seconds. In addition, during the contacting of the substrate with the boron precursor, the flow rate of the boron precursor may be less than 20 slm, or less than 10 slm, or less than 7 slm, or less than 5 slm, or even less than 3 slm. In addition, during the contacting of substrate with the boron precursor, the flow rate of the boron precursor may range from about 0.05 to 10 slm, from about 0.1 to 7 slm, or from about 0.1 to about 5 slm. In some embodiments, when the boron precursor is fed into the reaction chamber, argon is used as a carrier gas. When using argon as a carrier gas, it has been noticed that the pressure during the plasma pulse can be provided in a wider range. In some embodiments, when boron precursor is fed into the reaction chamber the reactant gas is used as a carrier gas.

In some embodiments, the excess boron precursor may be purged by stopping the flow of the vapor phase boron precursor while continuing to flow a carrier gas, a purge gas, or a gas mixture, for a sufficient time to diffuse or purge excess reactants and reactant byproducts, if any, from the reaction chamber. In some embodiments, the excess boron precursor may be purged with aid of one or more inert gases, such as nitrogen, helium or argon, that may be flowing throughout the cyclical deposition steps 104 and 106.

In some embodiments, the boron precursor may be purged from the reaction chamber for a time period of about 0.1 seconds to about 10 seconds, or about 0.3 seconds to about 5 seconds, or even about 0.3 seconds to about 1 second. Provision and removal of the boron precursor may be considered as the first or “boron phase” of the exemplary method 100.

Upon completion of the purging the reaction chamber of excess boron precursor and any reaction by-products, the cyclical deposition stage 108 of exemplary PEALD process 100 may continue with a second phase by means of a process block 106 comprising, contacting the substrate with a reactive species generated from a plasma produced from a gas comprising a reactant.

In the second phase, a second reactant comprising a reactive species generated from a plasma is provided to the substrate. In some embodiments, a reactant-based plasma is produced from a gas comprising a reactant. In some embodiments, the reactant may comprise a nitrogen and hydrogen. In some embodiments, the reactant may comprise ammonia. In some embodiments, the reactant may comprise a nitrogen/hydrogen mixture. In some embodiments, the reactant may comprise hydrazine.

For example, a nitrogen-based plasma may be generated by applying RF power from about 1000 W to 10000 W, or from about 3000 W to about 9000 W, or from about 4000 W to about 8000 W, or from about 5000 W to about 7000 W. In some embodiments, the plasma may be generated remotely. In some embodiments, a remote plasma unit may be used to generate the plasma. In some embodiments, the plasma is inductively-coupled (ICP) plasma. ICP allows for the generation of a high concentration of radicals, which can drive chemical reactions necessary for layer deposition. ICP also minimizes ion bombardment, reducing damage to the substrate and improving the conformality and quality of the deposited films, all while having a good growth per cycle. This makes ICP suitable for applications requiring precise control over film characteristics, such as the formation of boron nitride layers in high aspect ratio structures.

In some embodiments, the reactive species generated from the plasma may contact the substrate for a time period between about 0.5 seconds to about 20 seconds, or about 1 seconds to about 15 seconds, or even about 3 seconds to about 10 seconds. In some embodiments, the reactive species generated from the plasma may contact the substrate for a time period of between approximately 2 seconds and 12 seconds.

After a time period sufficient to completely saturate and react the previously absorbed molecular layer with the reactant-based plasma pulse, any excess reactant and reaction byproducts may be removed from the reaction chamber. As with the removal of the first reactant, i.e., the vapor phase boron precursor, this step may comprise stopping generation of reactive species and continuing to flow an inert gas, such as a gas comprising nitrogen, helium, and in some embodiments additionally argon. The inert gas flow may flow for a time period sufficient for excess reactive species and volatile reaction byproducts to diffuse out of and be purged from the reaction chamber. For example, the purge process may be utilized for a time period between about 0.1 seconds to about 10 seconds, or about 0.1 seconds to about 4.0 seconds, or even about 0.1 seconds to about 0.5 seconds. Together, the nitrogen-based plasma provision and removal represent a second phase, i.e., a reactive species phase 106, in the exemplary boron nitride PEALD process 100 of FIG. 1.

The method wherein the substrate is alternately and sequentially contacted with the vapor phase boron precursor and contacted with the reactive species generated from a gas comprising a nitrogen precursor may constitute a unit deposition cycle. In some embodiments of the disclosure, the exemplary PEALD process 100 may comprise repeating the unit deposition cycle one or more times 108. For example, the cyclical deposition stage 108 of exemplary PEALD process 100 may continue whether the desired thickness is not achieved, for example, if the thickness of the boron nitride film is insufficient for the desired device structure, then the PEALD process 100 may return to the process block 104 and the processes of contacting the substrate with the boron precursor and contacting the substrate with the reactant (process block 106) may be repeated one or more times. For example, if the thickness of the boron nitride is less than desired for a particular application, then steps 104 and 106 can be repeated one or more times. In some embodiments, the method comprises from at least 1 cycle to at most 1000 cycles, or from at least 2 cycles to at most 800 cycles, or from at least 3 cycles to at most 700 cycles, or from at least 4 cycles to at most 600 cycles, or from at least 5 cycles to at most 500 cycles, or from at least 10 cycles to at most 400 cycles, or from at least 20 cycles to at most 300 cycles. In some embodiments, the method comprises at most 1000 cycles, or at most 900 cycles, or at most 800 cycles, or at most 700 cycles, or at most 600 cycles, or at most 500 cycles, or at most 400 cycles, or at most 300 cycles, or at most 200 cycles, or at most 100 cycles, or at most 50 cycles, or at most 40 cycles, or at most 30 cycles, or at most 20 cycles, or a single cycle.

Once the boron nitride film has been deposited to a desired thickness the exemplary PEALD process 100 may end, and the boron nitride film may be subjected to additional processes to form a semiconductor device structure.

While the PEALD cycle is generally referred to herein as beginning with the boron phase 104, it is contemplated that in other embodiments the cycle may begin with the reactive species phase 106. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the boron phase. In some embodiments, one or more different PEALD cycles are provided in the deposition process.

In some embodiments, the growth rate of the boron nitride film per unit deposition cycle may be greater than 0.01 nanometers per cycle, or greater than 0.02 nanometers per cycle, or greater than 0.03 nanometer per cycle. In some embodiments, the growth rate of the boron nitride film per unit deposition cycle may be between about 0.01 and about 0.1 nanometer per cycle at a deposition temperature of greater than 250 °C.

In some embodiments, the boron nitride may be deposited to a thickness from about 1 nanometer to about 50 nanometers, or from about 5 nanometers to about 30 nanometers, or from about 5 nanometers to about 20 nanometers, or from about 1 nanometer to 10 nanometers. These thicknesses may be achieved in feature sizes (width) below about 100 nanometers, or below about 50 nanometers, or below about 30 nanometers, or below about 20 nanometers, or even below about 10 nanometers.

In some embodiments of the disclosure, the boron nitride may be deposited on a three-dimensional structure, e.g., a non-planar substrate comprising high aspect ratio features. In some embodiments, the step coverage of the boron nitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

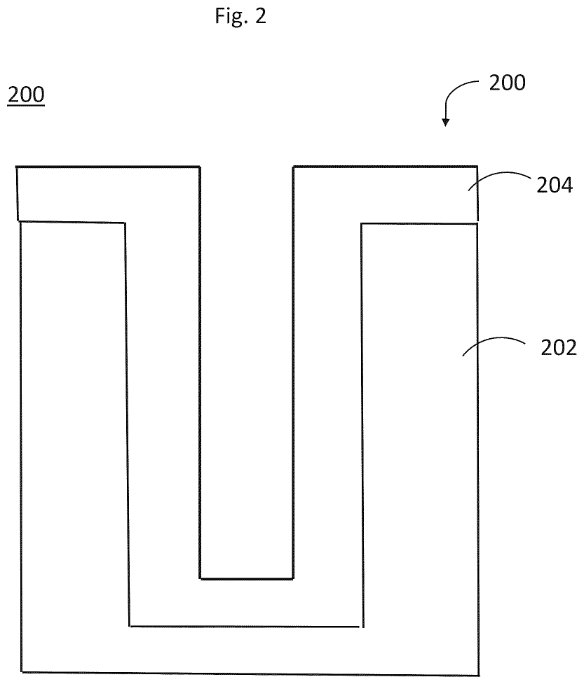

FIG. 2 illustrates a structure/a portion of a device 200 in accordance with additional examples of the disclosure. Device or structure 200 includes a substrate 202 and a layer of boron nitride (or boron nitride layer) 204 formed overlying substrate 202.

Substrate 202 can be or include any of the substrate material described herein. Layer of boron nitride 204 can be formed according to a method described herein. When layer 204 is formed using a cyclical deposition process, a concentration of boron, nitrogen and/or other constituents (e.g., carbon, hydrogen, or the like) in boron nitride layer 204 can vary from a bottom of boron nitride layer 204 to a top of boron nitride layer 204, for example, controlling an amount of boron precursor and/or reactant(s) and/or respective pulse times or number of pulses during one or more deposition cycles. In some cases, boron nitride layer 204 can have a stochiometric composition. Various properties of boron nitride layer 204 can be altered by altering an amount of boron, nitrogen, and/or other compounds in the layer or in a deposition cycle.

In some embodiments, the boron nitride deposited according to a method disclosed herein may have superior etch resistance to comparable boron nitride films deposited by prior processes. For example, the ratio of a wet etch rate of the boron nitride films deposited by a method of the disclosure relative to a wet etch rate of thermal silicon oxide (WERR) in dilute hydrofluoric acid (1:100) may be less than 1.0, or less than 0.5, or less than 0.4, or less than 0.2, or less than 0.1, or between approximately 0.1 and approximately 1.0.

In some embodiments of the disclosure, the boron nitride deposited according to a method disclosed herein may have a wet etch in dilute hydrofluoric acid (1:100) (at room temperature) of less than 1.5 nanometers/minute, or less than 1.0 nanometer/minute, or even less than 0.8 nanometers/minute.

In some embodiments of the disclosure, the boron nitride deposited according to a method disclosed herein may have a leakage value of less than 1E-6 A/cm² @2 MV/cm, such as less than 1E-8 A/cm² @2 MV/cm at a thickness of 10 nm.

In some embodiments of the disclosure, the boron nitride consists essentially of boron and nitrogen. In some embodiments, the boron nitride film may comprise a carbon doped boron nitride.

In some cases, the layer of boron nitride 204 is amorphous. In some cases, the layer of boron nitride 204 is not polycrystalline.

A dielectric constant of the layer of boron nitride 204 can be less than 4, less than 3.7, or less than 3.5. The dielectric constant can be greater than 2 or greater than 2.5 or greater than 2.7.

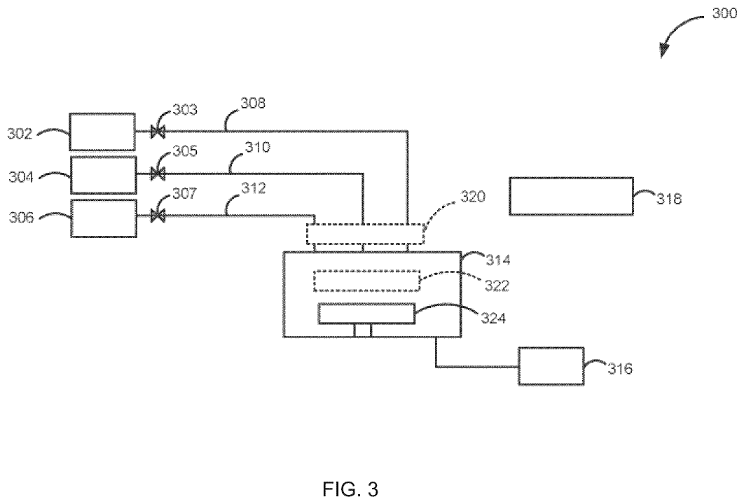

FIG. 3 illustrates a system 300 in accordance with yet additional exemplary embodiments of the disclosure. System 300 can be used to perform a method as described herein and/or form a structure or device portion as described herein.

In the illustrated example, system 300 includes one or more reaction chambers 314, a boron precursor source 302 in fluid communication via a first valve 303 with reaction chamber 314, a reactant source 304 in fluid communication via a second valve 305 with reaction chamber 314, a third gas source (e.g., a carrier and/or purge gas source) 306 in fluid communication via a third valve 307 with reaction chamber 314; an exhaust source 316, and a controller 318. System 300 can include a remote plasma source 320 to excite a gas from one or more sources 302-306.

Reaction chamber 314 can include any suitable reaction chamber, such as an ALD or CVD reaction chamber. Reaction chamber 314 can include a gas distribution system 322, such as a showerhead, and a susceptor 324 to retain a substrate.

Boron precursor source 302 can include a vessel and one or more boron precursors as described herein—alone or mixed with one or more carrier (e.g., inert) gases. Reactant source 304 can include a vessel and one or more reactants (e.g., nitrogen reactant) as described herein—alone or mixed with one or more carrier gases. Third gas source 306 can include one or more inert and/or carrier gases as described herein. Although illustrated with three gas sources 302-306, system 300 can include any suitable number of gas sources. Gas sources 302-306 can be coupled to reaction chamber 314 via lines 308-312, which can each include flow controllers, valves, heaters, and the like.

Exhaust source 316 can include one or more vacuum pumps.

Controller 318 can include electronic circuitry and software to selectively operate valves, manifolds, heaters, pumps and other components included in system 300. Such circuitry and components can operate to introduce precursors, reactants, and purge gases from the respective sources 302-306. Controller 318 can control timing of gas pulse sequences, temperature of the substrate and/or reaction chamber, pressure within the reaction chamber, and various other operations to provide proper operation of system 300. Controller 318 can include control software to electrically or pneumatically control valves to control flow of precursors, reactants and purge gases into and out of the reaction chamber 314. Controller 318 can include modules, such as a software or hardware component, e.g., a FPGA or ASIC, which perform certain tasks. A module can advantageously be configured to reside on the addressable storage medium of the control system and be configured to execute one or more processes. By way of example, controller 318 can be operably connected to first valve 303 and second valve 305 and configured and programmed to control: supplying a boron precursor in the reaction chamber and supplying a nitrogen-containing reactant to the reaction chamber to thereby deposit boron nitride on the substrate.

Other configurations of system 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 314. Further, as a schematic representation of an apparatus, many components have been omitted for simplicity of illustration, and such components may include, for example, various valves, manifolds, purifiers, heaters, containers, vents, and/or bypasses.

During operation of deposition system 300, substrates, such as semiconductor wafers (not illustrated), are transferred from, e.g., a substrate handling system to reaction chamber 314. Once substrate(s) are transferred to reaction chamber 314, one or more gases from gas sources 302-306, such as precursors, reactants, carrier gases, and/or purge gases, are introduced into reaction chamber 314 to deposit boron nitride.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a layer comprising boron and nitrogen on a surface of a substrate, the method comprising
providing a substrate into a reaction chamber, wherein the substrate comprises a 3D structure; and
executing a plurality of deposition cycles, a deposition cycle comprising;
providing a boron precursor in vapor phase in the reaction chamber;
providing a reactive species generated from a plasma produced from a reactant gas into the reaction chamber,
wherein the plasma is inductively-coupled plasma.

2. The method according to claim 1, wherein the reactant gas comprises nitrogen and hydrogen.

3. The method according to claim 2, wherein the reactant gas is selected from ammonia (NH₃), nitrogen/hydrogen mixture (N₂/H₂) and hydrazine (H₂H₄).

4. The method according to claim 1, wherein the 3D structure of the substrate comprises at least one of lateral and horizontal gaps.

5. The method according to claim 1, wherein the plasma is formed in a remote plasma unit.

6. The method according to claim 1, wherein the boron precursor is selected from the list of boron halide, borane, borazine and organoborane.

7. The method according to claim 6, wherein the boron halide comprises a molecule selected from the list consisting of boron triiodide, boron tribromide, boron trichloride, diboron tetrachloride, boron monofluoride, boron trifluoride and diboron tetrafluoride.

8. The method according claim 6, wherein the borane comprises a molecule selected from the list consisting of borane, diborane, tetraborane, pentaborane, decaborane and borane-ammonia complex.

9. The method according to claim 6, wherein the borazine comprises a molecule represented by the following general formula (I) 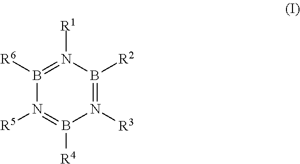
wherein R¹, R², R³, R⁴, R⁵, R⁶ are each independently selected from the group consisting of hydrogen, halogen, alkyl, alkenyl, and alkoxy.

10. The method according to claim 6, wherein the organoborane comprises a molecule selected from the list consisting of trimethylborane, triethylborane, 3-tris-(dimethylamino)borane, dimethylamine borane and triethylamine borane.

11. The method according to claim 1, wherein the method further comprises a purge step after the step of providing the boron precursor into the reaction chamber.

12. The method according to claim 1, wherein the method further comprises a purge step after the step of providing the reactive species into the reaction chamber.

13. The method according to claim 1, wherein the method further comprises using a carrier gas to provide the boron precursor into the reaction chamber.

14. The method according to claim 13, wherein the carrier gas comprises argon.

15. The method according to claim 1, wherein the reactant gas acts as a carrier gas.

16. The method according to claim 13, wherein the carrier gas and/or reactant gas is fed continuously into the reaction chamber.

17. The method according to claim 1, wherein the layer comprising boron and nitrogen comprises amorphous boron nitride.

18. The method according to claim 1, wherein the plasma RF power is in the range of 1000 to 10000 W.

19. A semiconductor processing apparatus comprising:
a reaction chamber comprising a substrate support for supporting a substrate;
a heater constructed and arranged to heat the substrate in the reaction chamber;
a remote plasma module comprising a radio frequency power source constructed and arranged to generate a plasma;
a reactant gas source in fluid communication with the plasma module;
a boron precursor source in fluid connection with the reaction chamber via one or more precursor valves; and,
a controller operably connected to the plasma module and the one or more precursor valves, and provided with a non-transitory computer readable medium programmed to cause the semiconductor processing apparatus to execute a plurality of deposition cycles, the deposition cycle comprising: providing a boron precursor in vapor phase in the reaction chamber; and providing a reactive species generated from a plasma produced from a reactant gas into the reaction chamber.
